(19) United States
(12) Patent Application Publication
(10) Pub. No.: US 2017/0110617 A1
(43) Pub. Date: Apr. 20, 2017

(54) DEVICE PROVIDED WITH AN OPTIMISED PHOTOVOLTAIC NETWORK PLACED IN FRONT OF AN IMAGE

(71) Applicant: SUNPARTNER TECHNOLOGIES, Rousset (FR)

(72) Inventors: Philippe CARDI, Greasque (FR); David COULON, Aix En Provence (FR); Badre KERZABI, Aix En Provence (FR)

(73) Assignee: SUNPARTNER TECHNOLOGIES, Rousset (FR)

(21) Appl. No.: 15/395,514

(22) Filed: Dec. 30, 2016

Related U.S. Application Data
(63) Continuation of application No. 14/649,387, filed on Jun. 3, 2015, now abandoned.

(30) Foreign Application Priority Data
Dec. 4, 2012 (FR) 12 03283

(51) Int. Cl. H01L 31/12; G02F 1/167; H01L 31/0468

(52) U.S. Cl. CPC H01L 31/12; H01L 31/0468; G02F 1/167; G02F 2203/02

(57) ABSTRACT

A network of photovoltaic strips positioned in front of an image causes a decrease in the luminosity of said image, which is not uniform for all of the colours and causes an optical moiré phenomenon that is perceived by the observer when they change their viewing angle. In order to rectify said decrease in visual quality of the image, the invention describes a suitable positioning and dimension of the photovoltaic strips in relation to the inter-pixels of the image.

The present invention relates to devices provided with photovoltaic elements intended to be placed in front of an image, and in which the dimensions and the arrangements of the photovoltaic elements are chosen in such a way as to minimize visual degradation of the image by the photovoltaic elements.

### STATE OF THE ART

Photovoltaic surfaces are used to produce electricity from ambient light which makes it possible to power, at least partially, certain appliances used in our everyday life. In order to preserve the esthetics of our environment it is desirable to make these photovoltaic surfaces either colored to avoid the black appearance of the conventional photovoltaic panels, or to make them as transparent as possible, to allow the environment of the photovoltaic surfaces to show, but not the photovoltaic surfaces themselves.

Not distorting the images which are seen through this transparent photovoltaic surface is essential, notably when the photovoltaic surface is a window, a transport vehicle windshield, or even when the image is a landscape.

This need is all the more evident when these images belong to electronic display devices such as, in particular, cell phones, computers, GPS navigators, watches, televisions, advertising displays.

Some techniques are already known for rendering a photovoltaic surface transparent without provoking the visual distortion of the image which is placed behind it, such as arranging photovoltaic elements in very thin parallel strips with a width that is smaller than the resolving power of the eye, thereby rendering the photovoltaic elements invisible to the naked eye.

However, since the production of electrical energy is proportional to the surface area of the photovoltaic elements, there is every benefit to be gained in multiplying the number of thin photovoltaic strips, the consequence of that being to create an obstacle to the incident light which illuminates the image if it is a passive image, or else to create an obstacle to the light emitted by the image if it is a landscape or an electronic image or a backlit image. In all cases, the image loses brightness proportionally to the surface area of the photovoltaic elements interposed between the observer and the image, and therefore proportionally to the number of thin strips which are used.

A trade-off is therefore always sought between a maximum of photovoltaic strips to produce a maximum of electricity and a minimum of photovoltaic strips so as to only marginally reduce the brightness of the image.

The width of the strips and the distance between them are chosen as a function of the distance from the observer such that his or her eye does not perceive the existence of these strips. Such will be the case if these values are less than the resolving power of the eye, i.e. an angle of 0.017 degree. Thus, for vision at 20 cm, this angle is equivalent to a distance between the strips which has to be less than 60 micrometers.

The case of electronic screens in which the pixels emit light, or indeed those which are backlit, presents particular features which are sometimes used in order to optimize the arrangement and the size of the photovoltaic strips in order to limit the loss of brightness of the screen. Thus, it is known from the document US 2007/0102035, that the strips can be arranged facing spaces between adjacent pixels, called inter-pixels, so as to only partially create an obstacle to the light emitted by the pixels. However, given the small size of the inter-pixels, the available photovoltaic surface area is minimal, and the production of electrical energy is infinitesimal.

It is also known from the document US 2012/236540, that the light emitted by the pixels can be redirected by an array of convergent lenses toward the spaces between the photovoltaic strips, which makes it possible to increase the width of the photovoltaic strips while reducing the loss of brightness of the image. However, this document does not describe the fact that the photovoltaic strips are positioned in such a way as to uniformly overlap all the pixels of the image. Furthermore, it is specified in paragraph [0037] of this document, that the lens array is positioned between the network of image areas and the network of photovoltaic cells. The additional lens array modifies the optical path of the light emitted by the backlighting, such that the light circumvents the photovoltaic areas so that, by virtue of the lens array, no Moiré effect can appear. This solution has a disadvantage, namely the integration of a lens array in such a thin structure. On the other hand, the problem that the present patent application seeks to resolve is how to avoid the moiré effects which appear upon a random positioning of an opaque photovoltaic network, on a network of pixels, and do so without a lens array to redirect the light.

Also known, from the document US 2010/245731 A1, is a network of photovoltaic cells which is overlapped by a network of colored filters. However, this document provides (paragraph [0050] and claim 1) for the photovoltaic cells to far better transmit their respective colors, which means that their material is semi-transparent for certain visible wavelengths. This document does not therefore present any solution to the case where the photovoltaic areas are opaque, which favors the appearance of Moiré effects because of the random masking of the pixels by the opaque photovoltaic areas.

In effect, it has been noted through trials that the quality of an image is degraded when photovoltaic strips overlap the pixels of the image randomly.

In effect, the pixels, notably the pixels of color screens, are generally made up of three basic colors, red, green, blue, (RGB), the brightness of which is controlled individually in order to give the desired color. Thus, for the pixels of LCD (liquid crystal display) type for example, this brightness is controlled by the rotation of a polarizing filter. Randomly placing a network of opaque photovoltaic strips in front of the pixels then provokes a decrease in the brightness of certain colors and not others, which is reflected in a degradation of the color of the image.

Also, the photovoltaic strips are often arranged in regular networks, that is to say that the distance between two adjacent strips is always identical and repetitive, but there is no strict relationship or alignment of the network of photovoltaic strips and the network of pixels, their relative arrangement being random. Because of this, certain strips overlap inter-pixels and others do not, and do this in a random manner, which provokes alternations of image areas in which the brightness is different. An optical Moiré effect then appears, which varies as a function of the angle of observation.

The need to resolve these various optical problems appears when there is a desire to maximally retain the quality of the basic image while increasing the density of the surface area of the photovoltaic elements which are placed on the surface, that is to say when it becomes necessary to overlap with photovoltaic material all or part of the pixels themselves, and not only the inter-pixels.

### AIM OF THE INVENTION

The main aim of the invention is to remedy the abovementioned drawbacks linked to the current state of the art.

The particular aim of the invention is to make it possible to increase the density of the surface area of photovoltaic elements positioned in front of an image, while limiting the degradation of the transparency and/or of the quality of the image which generally results therefrom.

### SUMMARY OF THE INVENTION

In its basic principle, the invention consists in positioning and dimensioning opaque functional elements, notably of photovoltaic type, in a specific manner, and in placing them in front of an image, in such a way that these position and dimension characteristics have the effect of reducing the loss of transparency and/or the visual degradation of said image when it is observed through said functional elements.

Hereinbelow, the invention will be described in the particularly advantageous case where the functional elements opaque to visible light are photovoltaic elements, it being understood that the invention extends to the case where these functional elements may be photovoltaic, or have another function (for example an electromagnetic antenna function), or a combination between a photovoltaic function and another function.

By convention, it will be said that the photovoltaic elements are “in front” of the image, that is to say on the same side as the observer of the image, the pixels of the image consequently being “behind” the photovoltaic elements.

The term “photovoltaic elements” is defined here to mean surfaces, preferably having repetitive geometrical patterns, capable of transforming a portion of the light that they receive into electricity. These photovoltaic elements can be made up of any known materials having this property of converting light energy into electrical energy, which is the case for example for crystalline, amorphous or organic silicon. These photovoltaic elements are moreover linked together, and linked to external components ensuring the collection and the use of the electrical energy produced, by electrical connections known to those skilled in the art and not described herein. These photovoltaic elements can take various forms, but, to facilitate their production by industrial means, they are preferably in the form of parallel strips of small width.

Hereinbelow, the term “photovoltaic strips” is therefore used by way of non-limiting example. The photovoltaic strips are one preferred variant out of the geometrical forms of the photovoltaic elements, generically, these elements being able to be in any form, and said form will be referred to as “photovoltaic area”.

In its principle, the invention is independent of the nature of the pixels. The term pixels as used here includes colored pixels having areas of several colors, for example RGB, as well as monochrome pixels.

The pixels will also, depending on their production technology, be able to be backlit or electroluminescent (as is the case notably with the pixels of so-called emissive screens), or printed (as is the case notably with the pixels of printed images), or even the pixels of reflective screens. They can even be pixels made up of colored or monochrome crystals placed on or incorporated in reflecting surfaces such as mirrors, such as, for example, the crystals of “cholesteric liquid crystal” type, also called ChLCD crystals.

In its most general embodiment, the subject of the invention is a functional device, notably of photovoltaic type, comprising, superposed, a semi-transparent functional surface, notably photovoltaic, and an image support, said semi-transparent functional or photovoltaic surface being made up of a set of areas of transparency allowing an image to show and a set of opaque functional or photovoltaic areas arranged according to a first regular pattern, the image being made up of pixels arranged according to a second regular pattern and some of which are wholly or partly overlapped by a photovoltaic area or, more generally, a functional area, characterized in that said functional or photovoltaic areas are dimensioned and are arranged in relation to the pixels in such a way that those of the image pixels which are overlapped by these areas, are all overlapped according to an overlap that is substantially identical in terms of position and surface area. By virtue of this design of the functional elements, notably photovoltaic, optimized in terms of dimension and positioning, the partial overlap of a pixel always produces the same optical effect, from one overlapped pixel to another, which makes it possible to avoid in particular the Moiré effects.

Obviously, the brightness of those of the pixels which are not overlapped at least partially by a photovoltaic area is unaffected by the invention.

In order to have the pixels overlapped at least partly by a photovoltaic area or all overlapped in the same way, the invention, in an advantageous embodiment, provides for said first regular pattern of the photovoltaic areas to be arranged according to a first constant pitch between consecutive photovoltaic areas, and for said second regular pattern of the pixels to be arranged according to a second constant pitch. However, this measure in itself is not sufficient to ensure a constant overlap of the pixels arranged partly under a photovoltaic element, since a progressive staggering of the networks of pixels and of the networks of photovoltaic elements would occur if the two pitches concerned were not closely linked.

To this end, the invention provides for said first pitch, that of the photovoltaic areas, to either be equal to the pitch of the pixels, or constitute a sub-multiple of this pitch.

In this way, there is an assurance that the pixels topped partly by a photovoltaic area are always topped by the same photovoltaic surface area, and that this surface area is always situated at the same point of the pixels concerned.

By way of example, with respect to an image made up of colored pixels having 3 color areas R, G, B, if a first row of pixels is overlapped by a photovoltaic area at the level of its red area R the same will apply for the other pixels of the row, and the brightness of the pixels overlapped partially with photovoltaic material will not be distorted from one pixel to the next.

Surprisingly and empirically, it has been found that the effect of the respective distribution of the photovoltaic areas and of the areas of pixels on the quality of the image is even better when said first pitch of the adjacent photovoltaic strips is at least 5 times smaller than the second pitch of the pixels of the image, or, which amounts to the same thing, the pitch of the inter-pixels.

Since the invention is independent of the nature of the pixels, it can be implemented with any type of pixel and any type of image.

However, in practice, the image support will advantageously be an emissive screen notably of LCD type, the pixels of the image then being made up of areas of colored pixels (R, G, B) or of areas of monochrome pixels.

Alternatively, the image support will be able to consist of a reflective screen, the pixels of the image then being made up of areas reflecting the ambient light. In particular, the image support used will be able to be a reflective support of electronic paper type (e-paper).

In an embodiment that is very simple to implement, the photovoltaic device according to the invention will comprise photovoltaic areas made up of parallel photovoltaic strips of width Lj delimiting strips of transparency of width Dx, and the colored or monochrome areas of the pixels of the image will in this case be also arranged in lines separated by mutually parallel non-colored lines, of width Ip and spaced apart by a distance Dp, and the photovoltaic strips will be parallel to the network of parallel lines formed by the non-colored lines. The photovoltaic strips can be active only on one face, or be active on two faces, in which case they will convert into electricity both the light from the outside of the device and the internal light from the pixels.

In this embodiment, the distance (Dx+Lj) between two adjacent photovoltaic strips is equal to or is a sub-multiple of the distance (Dp+Ip) between two consecutive lines of non-colored areas of the image.

The orientation of the photovoltaic strips and of the strips of pixels of the image, and of the inter-pixels on the device according to the invention will be able to be any orientation. Thus, these elements will be able to form horizontal straight lines or vertical straight lines or oblique straight lines and/or broken straight lines.

The photovoltaic device according to the invention will not be reserved to a particular technology for the production of the photovoltaic strips, the latter being able to be composed notably of crystalline, amorphous, organic silicon, and/or of a plurality of thin layers.

Similarly, the technology and the nature of the pixels will not be factors limiting the use of the invention, and the pixels of the image will be either emissive, of the backlit or electroluminescent type, or reflective, of the printed type or composed of colored crystals placed on or incorporated in mirror surfaces.

Similarly, the inter-pixels situated between the pixels or between the colored or monochrome areas of the pixels, will be able to have multiple appearances, and will be either transparent, or of uniform color, or white, or black.

Having succeeded in incorporating photovoltaic areas or strips in a device as described above, it is found that the concept can be extended to the incorporation of other opaque, non-photovoltaic functional elements, or a combination or a juxtaposition of photovoltaic elements and of other functional elements, depending on application-oriented needs of the device.

Thus, the device according to the invention will be able to be such that the photovoltaic areas or the photovoltaic strips as described previously are respectively replaced by, or combined with, functional areas or strips of another type.

One of the examples of useful functional elements, among others, is that in which the photovoltaic areas or strips are replaced by, wholly or partly, electrically conductive areas or strips suitable for forming an electromagnetic antenna, or by semiconductive areas or strips. In this way, the device according to the invention will be made a communicating device through electromagnetic means, by virtue of an antenna incorporated in the device but invisible to the naked eye.

Another subject of the invention is a screen for an electronic device, characterized in that it comprises a photovoltaic device, or more generally a functional device, as described above, this screen being able to be of the type reflective to ambient light (the photovoltaic areas or strips then being arranged above an image made up of pixels suitable for reflecting the ambient light), or of light-emissive type (the photovoltaic areas or strips then being arranged above an image made up of backlit or luminescent pixels).

Yet another subject of the invention is an electronic apparatus, characterized in that it comprises a device or a screen as described previously.

### DETAILED DESCRIPTION OF THE INVENTION

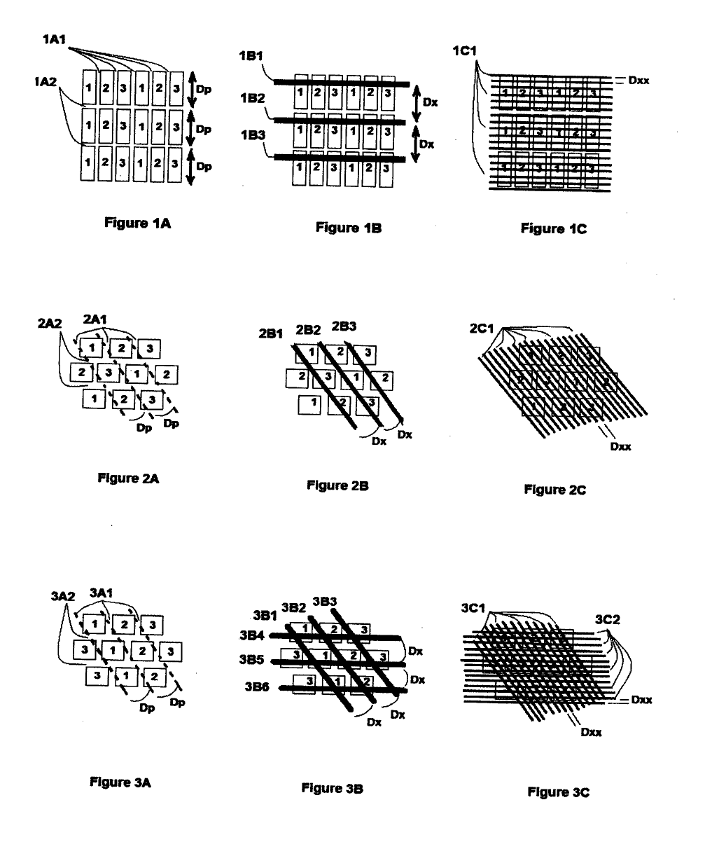

The invention is now described in more detail using the description of the indexed FIGS. 1A to 5.

The description is given by way of preferred example in the case where the photovoltaic strips or areas incorporated in the device are of photovoltaic type, but, as indicated previously, the invention extends to the incorporation of other functional elements in a device, in as much as this incorporation is done according to the same rules of dimensioning and of positioning in relation to the pixels of the image, as in the example described in relation to photovoltaic elements.

FIGS. 1A, 2A and 3A are three known examples of positioning of the colored areas of the pixels of an image, relative to one another.

FIGS. 1B, 2B and 3B respectively illustrate embodiments of the invention in which photovoltaic strips are superposed on the colored areas of FIGS. 1A, 2A, 3A, when these colored areas of the pixels and these photovoltaic strips are respectively horizontal, oblique, or both horizontal and oblique.

FIGS. 1C, 2C and 3C illustrate an embodiment of the invention in which the distance between adjacent photovoltaic strips of the preceding three FIGS. 1B, 2B, 3B has been divided by an integer factor, in this case the factor five.

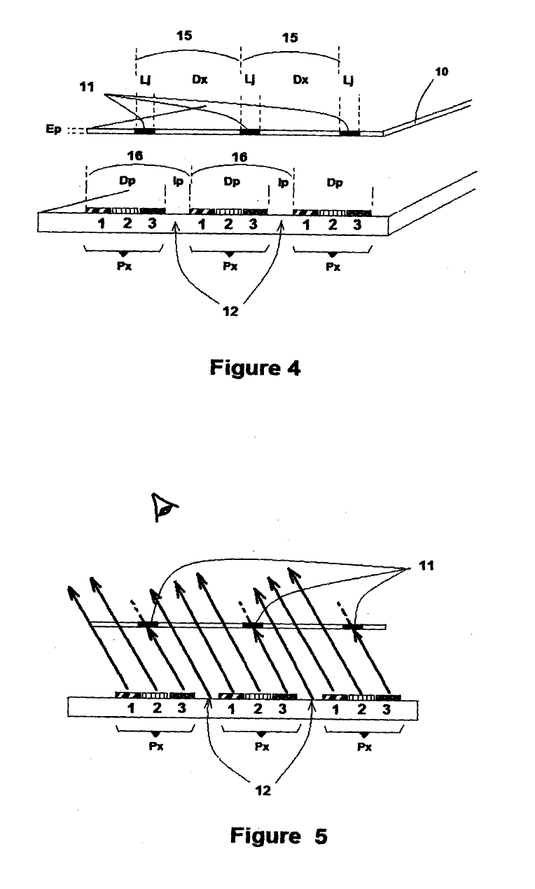

FIG. 4 is an exploded perspective schematic view of a photovoltaic device according to the invention, showing the dimensions and the relative positioning of the pixels of an image and of the photovoltaic strips superposed on certain areas of the image.

FIG. 5 is a schematic view similar to FIG. 4, showing the effect of a modification of the angle of observation on the perception of the image by an observer.

According to a preferred embodiment of the invention, a transparent surface is overlapped with parallel photovoltaic strips (FIG. 5) of which the length is Ll, the width is Lj, the thickness is Ep and the distance which separates two consecutive strips is denoted Dx. The width of the strips is smaller than the resolving power of the human eye, i.e. 0.017 degree, such that an observer for example placed at 20 cm or more from the transparent surface will not perceive the strips individually but will perceive only a reduction in the transparency of said surface if Lj in this example is less than 60 micrometers. The transparent surface which is overlapped with the photovoltaic strips therefore becomes semi-transparent to the human eye. This semi-transparent surface will be called a “photovoltaic plate” when the latter is produced in the form of a thin support positioned in front of an image made up of a network of pixels.

The “photovoltaic plate” is positioned on an image of which each pixel is made up of three colored areas, red (1), green (2) and blue (3). The regular arrangement of each of the pixels relative to one another forms an ordered network of pixels and three sub-networks of colored areas, each of these sub-networks being made up of all the colored areas of one and the same color.

Non-colored spaces are also observed between the colored areas of one and the same pixel, or between the colored areas of adjacent pixels, these spaces being able to form rectilinear or broken, horizontal or vertical or oblique lines. These spaces that are here called “non-colored”, are spaces which do not contain any colored or monochrome pixels. They can therefore equally be transparent or even have a uniform color, often consisting of the color of the support of the image, such as white or black for example. These spaces will hereinafter be designated by the generic term of “inter-pixels”.

Each of the three sub-networks of colored areas itself describes lines which can be rectilinear or triangular, horizontal, vertical or oblique.

The photovoltaic strips are mutually parallel and positioned in front of said colored areas and in front of said non-colored spaces, and, according to the invention, this overlap is such that the surface area of overlap and the positioning of the overlap of said photovoltaic strips is the same for all the colored areas (1, 2, 3) of the image.

The first consequence will be that the observer will perceive only an overall decrease in the brightness of the image without any alteration of its color, that is to say without observing a dominant color which might appear because the latter would have been overall less overlapped by photovoltaic elements than the other colors.

More specifically, this invention spaces the adjacent photovoltaic strips apart by a distance Dx such that the pitch Dx+Lj is equal to, or is a sub-multiple of, the distance Dp+Ip which is the pitch which separates the lines formed by the non-colored spaces, these lines being those which are parallel to the photovoltaic strips.

This feature has the second consequence of eliminating the appearance of Moiré areas when the angle at which the device is viewed by an observer is modified. In effect, as schematically represented in FIG. 5, the modification of the viewing angle of the observer leads to the apparent displacement of the photovoltaic strips relative to the colored areas and relative to the non-colored areas. This apparent displacement occurs according to an optical parallax phenomenon which virtually displaces the photovoltaic strips at right angles to their length. Thus, certain photovoltaic strips may overlap non-colored areas which provokes an imbalance between the surface areas of overlap of each colored area and therefore an optical Moiré effect.

To avoid this phenomenon when the angle of observation is modified, the first pitch Dx+Lj between two consecutive photovoltaic strips is equal to, or is a sub-multiple of, the second pitch Dp+Ip between two lines of consecutive non-colored areas which are parallel to said photovoltaic strips.

According to a particular advantageous embodiment, the pitch Dx+Lj between the photovoltaic strips is at least 5 times smaller than the pitch Dp+Ip between two consecutive lines of non-colored areas which are parallel to said photovoltaic strips.

The increase in the number of photovoltaic strips which overlap each colored area means commensurately reducing the width Lj of the strips and makes it possible to proportionally minimize the Moiré defect which appears when, from certain angles of observation, photovoltaic strips are positioned on the non-colored areas.

FIGS. 1A, 2A and 3A are three known examples of positioning of the fundamental colored areas (1, 2, 3) of an image relative to one another.

A triplet of colors 1(red), 2(green), 3(blue) defines a pixel which is the basic component of the image. All of the colored areas (1, 2, 3) are arranged in an ordered network which can take the form:
of a rectilinear meshing (FIG. 1A) in which the repetitive sequence of the colors in the horizontal lines is 1, 2, 3, 1, 2, 3 . . . and of which each vertical line comprises the same series of colors.

The non-colored spaces which separate the colored areas (1, 2, 3) form horizontal lines (1A1) and vertical lines (1A2),
of a crossed meshing (FIG. 2A) in which the repetitive sequence in the oblique lines is 1, 3, 2, 1, 3, 2 . . . and the sequence of the horizontal lines is 1, 2, 3, 1, 3, 1 . . . . The non-colored spaces which separate the colored areas (1, 2, 3) form horizontal lines (2A2) and oblique lines (2A1).
of a crossed meshing (FIG. 3A) in which the repetitive sequence in the oblique lines is a series of colored areas of the same color, for example 1, 1, 1, 1 . . . and the sequence in the horizontal lines is 1, 2, 3, 1, 2, 3, 1 . . . . The non-colored spaces which separate the colored areas (1, 2, 3) form horizontal lines (3A2) and oblique lines (3A1).

FIGS. 1B, 2B, 3B are particular embodiments according to the invention in which the photovoltaic strips partly overlap the colored areas (1, 2, 3) of the three preceding figures (FIGS. 1A, 2A, 3A). The overlap is such that the surface area of overlap of all the colored areas (1, 2, 3) by the photovoltaic material is identical in size and in position, and the displacement of said strips at right angles to their length does not modify this identity. This is made possible by virtue of the fact that the distance Dx+Lj which separates the photovoltaic strips is equal to the distance Dp+Ip which separates the lines of the non-colored areas which are parallel to said photovoltaic strips.

FIG. 1B illustrates the case where each photovoltaic strip (1B1, 1B2, 1B3) overlaps a horizontal line of colored areas (1, 2, 3, 1, 2, 3 . . . ) FIG. 2B illustrates the case where each photovoltaic strip (2B1, 2B2, 2B3) is oblique and overlaps an oblique line of colored areas (1, 3, 2, 1, 3, 2 . . . ).

In order to increase the density of the photovoltaic surface area, the pitch Dx+Lj can be divided by an integer without modifying the image quality sought.

According to another embodiment (FIG. 3B), and still in order to increase the density of the photovoltaic surface area, the photovoltaic strips (3B4, 3B5, 3B6) and (3B1, 3B2, 3B3) overlap both lines of horizontal colored areas (1, 2, 3, 1, 2, 3 . . . ) and lines of oblique colored areas (1, 1, 1, . . . 2, 2, 2 . . . 3, 3, 3 . . . ).

FIGS. 1C, 2C, 3C are other particular embodiments of a device according to the invention, in which the pitch of the photovoltaic strips Dxx+Lj is at least five times less than the pitch Dp+Ip between the lines of the non-colored spaces.

FIG. 1C illustrates this particular embodiment in the case of a network with rectilinear meshing of colored areas. The photovoltaic strips are here horizontal (1C1) but they could also be vertical (not illustrated).

FIGS. 2C and 3C illustrate the case of a network with oblique meshing in which the photovoltaic strips are oblique (2C1, 3C1) and/or horizontal (3C2).

A concrete exemplary embodiment will now be described:

A device according to the invention is made up of a rectangular transparent photovoltaic plate measuring 80×60 mm and 400 μm thick on which has been deposited a network of parallel photovoltaic strips in the form of thin amorphous silicon layers. The photovoltaic strips are Lj=30 μm wide and are spaced apart by Dx=125 μm, which makes a network in which the pitch is Dx+Lj=155 μm. This photovoltaic plate is positioned on a cell phone LCD screen in which the pixels are arranged in a rectilinear network in which the pitch is also 155 μm, i.e. Dp=130 μm for the width and the height of the pixel and Ip=25 μm for the inter-pixel value.

The value of the pitch for the network of pixels and for the network of photovoltaic strips is identical, so the positioning of the photovoltaic plate in front of the screen of the cell phone does not provoke any deterioration in the colors of the image, only an overall lowering of its brightness by 20% corresponding to the percentage of surface coverage of the photovoltaic strips.

This absence of deterioration in the colors of the image is maintained even when viewing the screen from different angles because, according to the features of the invention, the overall coverage of the photovoltaic strips remains identical for each of the three fundamental screen colors.

This image quality would remain identical even with a pitch two times less for the photovoltaic strips, that is to say with a pitch of 77 μm corresponding to a strip width of Lj=15 μm and spacings Dx=62 μm.

### Advantages of the Invention

Ultimately, the invention addresses the fixed aims well by increasing the visual quality of an image when the latter is positioned behind a network of photovoltaic strips according to the rules of the invention, that is to say by dimensioning and by positioning said photovoltaic strips in a specific manner relative to the pixels and to the inter-pixels of the image.

It can further be seen that this result is obtained without it being necessary to interpose an optical unit between the pixels of the image and the photovoltaic strips to direct the brightness of the image around the photovoltaic strips.

Moreover, the principle and the dimensioning of the photovoltaic device according to the invention are independent of the type of image displayed, in as much as the latter is structured in pixels according to a regular pattern. In particular, when the device according to the invention is associated with an image displayed on an electronic screen, it does not depend on the screen technology or image support used, and is equally suited to emissive screens, for example of LCD type, to reflective screens, and to color or monochrome screens.

1. A device comprising, superposed, a partially transparent functional surface and an image support, said partially transparent functional surface comprising a set of areas of transparency allowing an image to show and a set of opaque functional areas arranged according to a first regular pattern, the image comprising pixels arranged according to a second regular pattern, at least some of the pixels being wholly or partly overlapped by at least one of the opaque functional areas,
wherein said opaque functional areas are dimensioned and are arranged in relation to the pixels in such a way that those of the image pixels which are overlapped by opaque functional areas, are all overlapped according to an overlap that is substantially identical in position and surface area,
wherein said first regular pattern of the opaque functional areas defines a first constant pitch between consecutive opaque functional areas and said second regular pattern of the pixels defines a second constant pitch, and
wherein said first pitch of the adjacent opaque functional areas is at least 5 times smaller than said second pitch.

2. The device as claimed in claim 1, wherein the opaque functional areas are photovoltaic areas comprising an opaque photovoltaic material.

3. The photovoltaic device as claimed in claim 1, wherein the image support is an emissive screen of LCD type, the pixels of the image being made up of areas of colored pixels or of areas of monochrome pixels.

4. The device as claimed in claim 1, wherein the image support is a reflective screen, of electronic paper type, the pixels of the image being made up of colored or monochrome areas reflecting the ambient light.

5. The device as claimed in claim 2, wherein the photovoltaic areas are made up of parallel functional strips of width Lj delimiting strips of transparency of width Dx, and wherein the colored or monochrome areas of the pixels of the image are arranged in lines separated by non-colored areas forming parallel lines of width Ip and spaced apart by a distance Dp, said functional strips being parallel to at least one network of said parallel lines formed by the non-colored areas.

6. The device as claimed in claim 5, wherein the distance between two adjacent functional strips is equal to or is a sub-multiple of the distance between two consecutive lines of non-colored areas of the image.

7. The device as claimed in claim 5, wherein said functional strips are active photovoltaic strips on one face or on two faces, and are composed of an organic or inorganic semiconductor material, and/or of a plurality of thin layers.

8. The device as claimed in claim 1, wherein the pixels of the image are either emissive, of the backlit or electroluminescent type, or reflective, of the printed type or composed of colored crystals placed on or incorporated in mirror surfaces.

9. The device as claimed in claim 1, wherein the non-colored areas of the image form horizontal straight lines or vertical straight lines or oblique straight lines and/or broken straight lines.

10. The device as claimed in claim 1, wherein inter-pixels situated between the pixels or between colored or monochrome areas of the pixels, are either transparent, or of uniform color, or white, or black.

11. The device as claimed in claim 1, wherein the device combines functional areas or strips of photovoltaic type with functional areas or strips of another type.

12. The device as claimed in claim 11, wherein the functional areas or strips of another type are electrically conductive areas or strips forming an electromagnetic antenna.

13. A screen for an electronic device, wherein the screen comprises a device as claimed in claim 1.

14. The screen as claimed in claim 13, wherein the screen is of the type reflective to ambient light, the functional areas or strips, of photovoltaic type or non-photovoltaic type, are arranged above an image made up of pixels for reflecting the ambient light.

15. The screen as claimed in claim 13, wherein the screen is of light-emissive type, the functional areas or strips being arranged above an image made up of backlit or luminescent pixels.

16. An electronic apparatus, comprising a device as claimed in claim 1.

17. An electronic apparatus, comprising a screen as claimed in claim 13.
